(19) United States
(12) Patent Application Publication
(10) Pub. No.: US 2013/0074918 A1
(43) Pub. Date: Mar. 28, 2013

(54) VACUUM WINDOW GLAZING INCLUDING SOLAR CELL AND MANUFACTURING METHOD THEREOF

(71) Applicants: Jin Woo Jeong, Daejeon (KR); Yoon Ho Song, Daejeon (KR); Sung Youl Choi, Ulsan (KR); Je Ha Kim, Daejeon (KR); Jong Tae Moon, Gyeryong-si (KR); Jung Wook Lim, Daejeon (KR); Hun Kyun Pak, Daejeon (KR)

(72) Inventors: Jin Woo Jeong, Daejeon (KR); Yoon Ho Song, Daejeon (KR); Sung Youl Choi, Ulsan (KR); Je Ha Kim, Daejeon (KR); Jong Tae Moon, Gyeryong-si (KR); Jung Wook Lim, Daejeon (KR); Hun Kyun Pak, Daejeon (KR)

(73) Assignee: ELECTRONICS AND TELECOMMUNICATIONS RESEARCH INSTITUTE, Daejeon (KR)

(21) Appl. No.: 13/561,226

(22) Filed: Jul. 30, 2012

(30) Foreign Application Priority Data
Sep. 28, 2011 (KR) 10-2011-0098294

(51) Int. Cl. H01L 31/0232; C03C 27/06; H01L 31/0256; H01L 31/0296; H01L 31/0272; B32B 37/14; H01L 31/0264

(52) U.S. Cl. 136/256; 156/60; 156/109; 136/252; 136/261; 136/262; 136/260; 136/263

(57) ABSTRACT

Disclosed are vacuum window glazing including a solar cell function and a manufacturing method thereof. The vacuum window glazing includes a first sheet glass, a second sheet glass that is vacuum-bonded to the first sheet glass; a vacuum layer that is formed between the first sheet glass and the second sheet glass; and a solar cell panel that is formed on a surface of the second sheet glass in a direction of the vacuum layer. By this configuration, power can be produced through the solar cell formed within the vacuum window glazing while more increasing the heat insulation effect of the vacuum window glazing, and the cooling and heating efficiency of the building can be greatly improved using the outer wall covered with glass.

### CROSS-REFERENCE TO RELATED APPLICATIONS

This application is based on and claims priority from Korean Patent Application No. 10-2011-0098294, filed on Sep. 28, 2011, with the Korean Intellectual Property Office, the disclosure of which is incorporated herein in its entirety by reference.

### TECHNICAL FIELD

The present disclosure is vacuum window glazing capable of producing power using a solar cell and a manufacturing method thereof.

### BACKGROUND

Recently, cases of constructing a building by covering an outer wall of a building with glass have been increased so as to enhance the aesthetic of the building exterior. However, in the case of covering the outer wall of the building with glass, the aesthetic of the building may be enhanced but thermal efficiency of the building may be degraded due to introduction of sun light or thermal loss through glass. In order to supplement the disadvantages of the outer wall covered with glass or glass windows, a double glazed window and a triple glazed window in which a vacuum layer is formed therein have been introduced.

FIGS. 1A and 1B are diagrams showing a structure of double vacuum window glazing according to the related art.

In the structure of the vacuum window glazing according to the related art, as shown in FIGS. 1A and 1B, sides of two sheet glasses 101 and 103 that are spaced apart from each other at a predetermined interval are sealed with a sealing material 93 such that a space between the two sheet glasses 101 and 103 is maintained in a vacuum state. A plurality of spacers 94 are formed between the two sheet glasses 101 and 103 to prevent the sheet glasses from being deformed due to an atmospheric pressure.

Meanwhile, a solar cell is a device converting solar energy into electric energy. To this end, research into single crystalline, polycrystalline, and amorphous silicon, copper indium gallium selenide (CIGS), dye-sensitized solar cell (DSSC), and the like, has been actively conducted. Recently, a building integrated photovoltaic system generating electricity by using a building integrated solar module as an exterior material of a building has been prevalently distributed.

Generally, a solar cell is easily deteriorated when being exposed to sun light and has the reduced light conversion efficiency when the internal temperature of the solar cell rises. In the case of the silicon solar cell, it is known that as temperature rises 1° C., the light conversion efficiency is reduced 0.5%.

### SUMMARY

The present disclosure has been made in an effort to provide vacuum window glazing having a solar cell function capable of producing power through a solar cell while increasing energy efficiency of a building due to a heat insulation effect of the vacuum window glazing implemented by bonding a solar cell to the vacuum window glazing and a manufacturing method thereof.

A first exemplary embodiment of the present disclosure provides vacuum window glazing, including: a first sheet glass; a second sheet glass that is vacuum-bonded to the first sheet glass; a vacuum layer that is formed between the first sheet glass and the second sheet glass; and a solar cell panel that is formed on a surface of the second sheet glass in a direction of the vacuum layer. The vacuum window glazing may further include: a third sheet glass that is bonded to a surface the second sheet glass in an opposite direction of the vacuum layer.

A second exemplary embodiment of the present disclosure provides vacuum window glazing, including: a first sheet glass; a second sheet glass that is vacuum-bonded to the first sheet glass; a vacuum layer that is formed between the first sheet glass and the second sheet glass; a solar cell panel that is formed on a surface of the first sheet glass in a direction of the vacuum layer; and a coating layer that is formed on a surface of the second sheet glass in the vacuum layer direction and has predetermined reflectivity. The vacuum window glazing may further include: a third sheet glass that is bonded to a surface of the second sheet glass in an opposite direction of the vacuum layer.

The solar cell panel may be wholly or partially translucent and may be formed of inorganic materials including silicon, CIGS, or CdTe.

A third exemplary embodiment of the present disclosure provides vacuum window glazing, including: a first sheet glass; a second sheet glass that is vacuum-bonded to the first sheet glass; a vacuum layer that is formed between the first sheet glass and the second sheet glass; a third sheet glass that is bonded to a surface of the second sheet glass in an opposite direction of the vacuum layer; and a solar cell panel that is formed between the second sheet glass and the third sheet glass, wherein the solar cell panel is formed of an organic material including a dye-sensitized solar cell (DSSC).

A method for manufacturing vacuum window glazing having a vacuum layer between a first sheet glass and a second sheet glass according to the first exemplary embodiment of the present disclosure, the method includes: forming a solar cell panel of inorganic materials on a surface of the second sheet glass in a direction of the vacuum layer; and sealing and bonding the first sheet glass and the second sheet glass. The method may further include: bonding a third sheet glass to the surface of the second sheet glass in an opposite direction of the vacuum layer.

A method for manufacturing vacuum window glazing having a vacuum layer between a first sheet glass and a second sheet glass according to the second exemplary embodiment of the present disclosure, the method includes: forming a solar cell panel of inorganic materials on a surface of the first sheet glass in a direction of the vacuum layer; forming a coating layer on a surface of the second sheet glass in the vacuum layer direction; and sealing and bonding the first sheet glass and the second sheet glass. The method may further include bonding a third sheet glass to the surface of the second sheet glass in an opposite direction of the vacuum layer.

### BRIEF DESCRIPTION OF THE DRAWINGS

FIGS. 1A and 1B are diagrams showing a structure of double vacuum window glazing according to the related art.

FIGS. 2A and 2B are configuration diagrams of vacuum window glazing according to a first exemplary embodiment of the present disclosure.

FIG. 3 is a configuration diagram of vacuum window glazing according to a second exemplary embodiment of the present disclosure.

FIG. 4 is a configuration diagram of vacuum window glazing according to a third exemplary embodiment of the present disclosure.

FIG. 5 is a flow chart of a method of manufacturing vacuum window glazing according to the first exemplary embodiment of the present disclosure.

FIG. 6 is a flow chart of a method of manufacturing vacuum window glazing according to the second exemplary embodiment of the present disclosure.

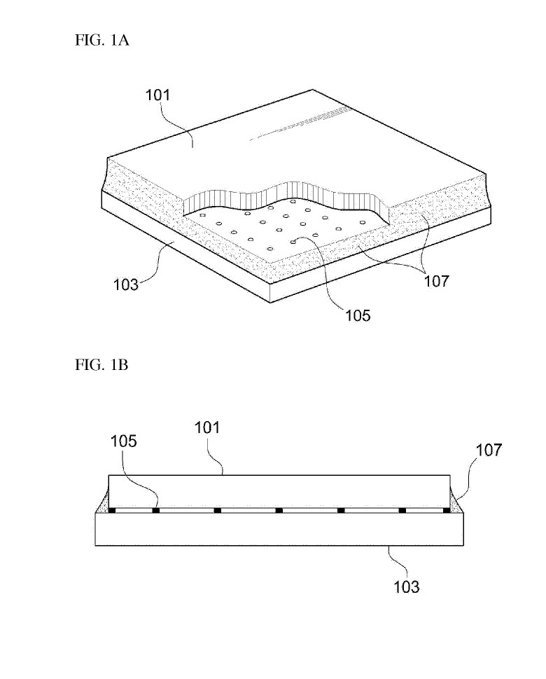

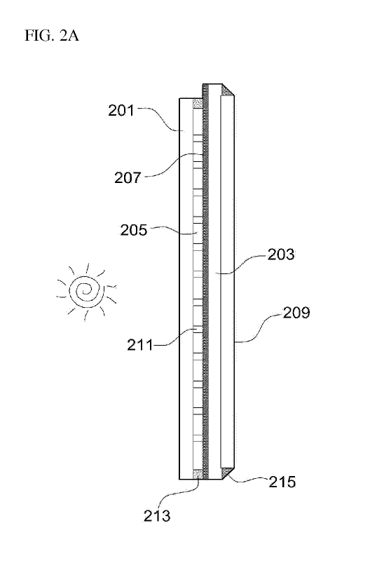

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here

The above-mentioned objects, features and advantages will be described below in detail with reference to the accompanying drawings so that a person with ordinary skill in the art to which the present disclosure pertains may easily perform the technical ideas of the present disclosure. In the following description, well-known arts will not be described in detail when it is judged that they may unnecessarily obscure the present disclosure. Hereinafter, exemplary embodiments of the present disclosure will be described in detail with reference to the accompanying drawings.

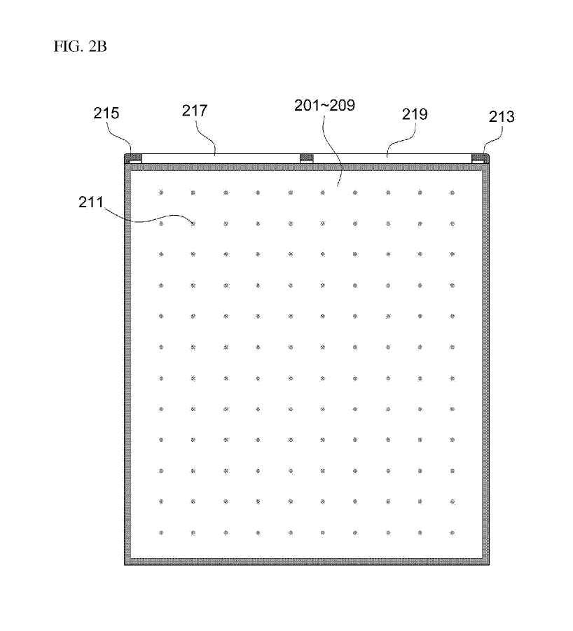

FIGS. 2A and 2B are configuration diagrams of vacuum window glazing according to a first exemplary embodiment of the present disclosure.

Referring to FIGS. 2A and 2B, vacuum window glazing according to a first exemplary embodiment of the present disclosure includes a first sheet glass 201, a second sheet glass 203 vacuum-bonded to a first sheet glass 201, a vacuum layer 205 formed between the first sheet glass 201 and the second sheet glass 203, and a solar cell panel 207 formed a surface of the second sheet glass 203 in a vacuum layer 205 direction and is formed to expose output electrodes 217 and 219 for outputting electricity generated from the solar cell panel 207 to the outside. The vacuum window glazing may further include a third sheet glass 209 that is bonded to the surface of the second sheet glass 203 in an opposite direction of the vacuum layer 205.

A space between the first sheet glass 201 and the second sheet glass 203 is vacuum-sealed with a sealing material 213 such as glass frit, and the like, so as to be maintained in a vacuum state and may be formed with a plurality of spacers 211 having a predetermined thickness so as to prevent glass from being deformed and broken due to an atmospheric pressure.

The first sheet glass 201 provided at the outside of the building is directly input with sun light and therefore, may be formed of low emissivity glass having high infrared reflectivity. When using the low emissivity glass, the increase in temperature of the solar cell is prevented and therefore, the light conversion efficiency of the solar cell may be maintained highly.

In the exemplary embodiment of the present disclosure, the solar cell panel 207 is formed on the surface of the second sheet glass 203 in the vacuum layer 205 direction. In this case, the increase in temperature of the solar cell panel 207 can be prevented and the solar cell panel 207 can be protected from humidity, pollutants, or chemicals, by separating the solar cell panel 207 from the first sheet glass 201 heated by sun light through the vacuum layer 205.

In the solar cell panel 207, the vacuum window glazing is wholly or partially translucent, and inorganic materials including silicon, copper indium gallium sulfur (CIGS), cadmium telluride (CdTe), and the like, having no reduction in a degree of vacuum due to outgassing are appropriate to form the solar cell panel 207 within the vacuum window glazing. Organic materials including a dye-sensitized solar cell (DSSC), or the like, are not appropriate to form the solar cell panel 207.

In order to increase the strength of the vacuum window glazing and obtain an additional heat insulation effect, the third sheet glass 209 is attached to the outside of the second sheet glass 203, and therefore, the third sheet glass 209 and the second sheet glass 203 may be bonded to each other using the sealing material 215. In this case, degradation in heat insulation performance due to heat exchange can be prevented by injecting air, inert gases such as argon (Ar), krypton (Kr), xenon (Xe), or the like, between the second sheet glass 203 and the third sheet glass 209. A heating layer (not shown) may be further formed between the second sheet glass 203 and the third sheet glass 209. In this case, a glass surface is heated by partially using power generated from the solar cell panel 207 and thus, the cooling of the glass surface can be prevented, thereby increasing heating efficiency. Indoor environments may be further comfortable by preventing the glass window from being condensed and fogged.

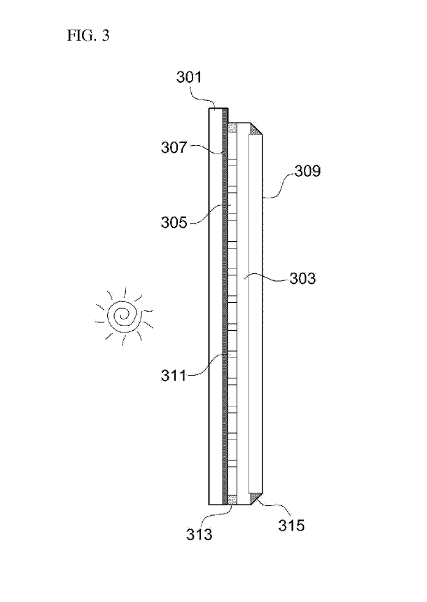

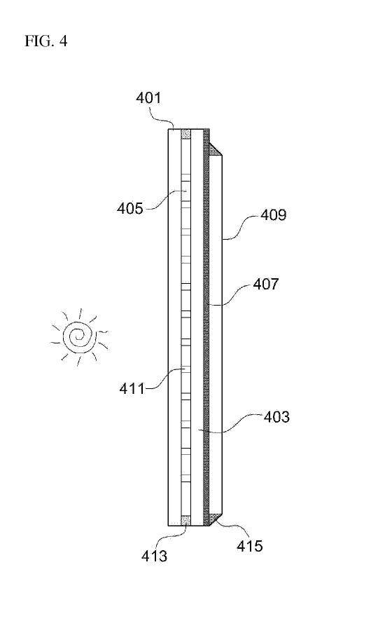

FIG. 3 is a configuration diagram of vacuum window glazing according to a second exemplary embodiment of the present disclosure.

Referring to FIG. 3, the vacuum layer according to the second exemplary embodiment of the present disclosure includes a first sheet glass 301, a second sheet glass 303 vacuum-bonded to the first sheet glass 301, a vacuum layer 305 formed between the first sheet glass 301 and the second sheet glass 303, a solar cell panel 307 formed on first sheet glass 301 in a vacuum layer 305 direction, and a coating layer (not shown) formed on a surface of second sheet glass 303 in the vacuum layer 305 direction and having predetermined reflectivity. The vacuum window glazing may further include a third sheet glass 309 that is bonded to the surface of the second sheet glass 303 in an opposite direction of the vacuum layer 305.

According to the exemplary embodiment of the present disclosure, the solar cell panel 307 may be formed in an inner surface of the first sheet glass 301. In this case, the coating layer having appropriate reflectivity is formed on the second sheet glass 303 opposite to the first sheet glass 301 to reflect light transmitting the solar cell panel 307 from a back surface, thereby increasing light absorption of solar cell panel 307. In this case, the reflectivity may be increased by optimizing the interval between the first sheet glass 301 and the second sheet glass 303.

Similar to FIG. 2, a plurality of spacers may be formed between the first sheet glass 301 and the second sheet glass 303, which may be bonded to each other in a vacuum state by a sealing material 313. The second sheet glass 303 and the third sheet glass 309 may be bonded to each other by a sealing material 315, inert gases may be injected between the second sheet glass 303 and the third sheet glass 309, and a heating layer may be formed. Characteristics of the rest components and effects according thereto are the same as those described with reference to FIG. 2.

FIG. 4 is a configuration diagram of vacuum window glazing according to a third exemplary embodiment of the present disclosure.

Referring to FIG. 4, the vacuum window glazing according to the third exemplary embodiment of the present disclosure includes a first sheet glass 401, a second sheet glass 403 vacuum-bonded to first sheet glass 401, a vacuum layer 405 formed between the first sheet glass 401 and the second sheet glass 403, a third sheet glass 409 bonded to a surface of the second sheet glass 403 in a direction opposite to vacuum layer 405, and a solar cell panel 407 formed between the second sheet glass 403 and the third sheet glass 409. The vacuum layer 405 may be formed with a plurality of spacers 411 and vacuum-bonded thereto by a sealing material 413.

In the exemplary embodiment of the present disclosure, the solar cell panel 407 is formed between the second sheet glass 403 and the third sheet glass 409, rather than in the vacuum layer 405. In this case, the solar cell formed of organic materials including DSSC may be used and DSSC needs to be manufactured at low temperature so as to be formed on a glass substrate. The second sheet glass 403 and the third sheet glass 409 on which the DSSC is formed are shielded from the outside by using the sealing material 415 and inert gases, or the like, may be filled between the second sheet glass 403 and the third sheet glass 409.

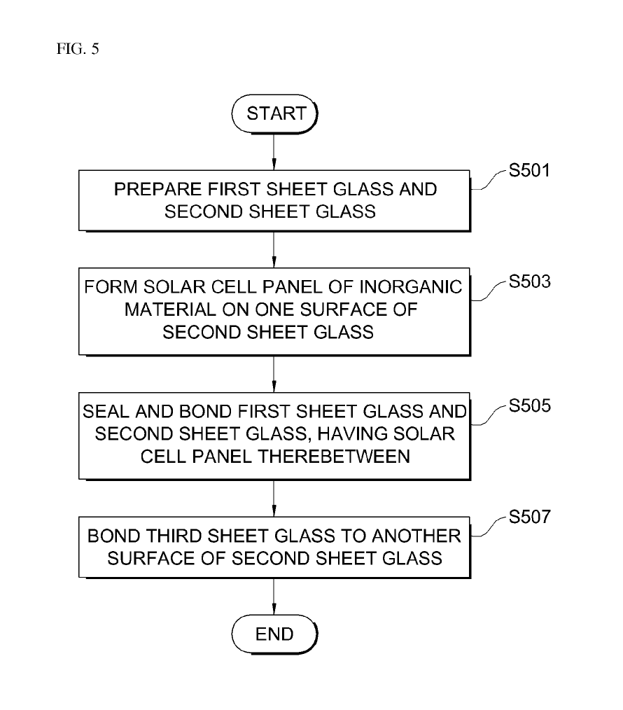

FIG. 5 is a flow chart of a method for manufacturing vacuum window glazing according to a first exemplary embodiment of the present disclosure.

Referring to FIG. 5, the method for manufacturing vacuum window glazing according to the first exemplary embodiment of the present disclosure includes preparing the first sheet glass and the second sheet glass (S501), forming the solar cell panel formed of inorganic materials on one surface of the second sheet glass (S503), sealing and bonding the first sheet glass and the second sheet glass, having the solar cell panel mounted therebetween (S505), and bonding the third sheet glass to another surface of the second sheet glass (S507).

At S501, the first sheet glass exposed to the outside and directly input with sun light may be formed of low emissivity glass having high infrared reflectivity. As a result, the increase in temperature of the solar cell is prevented and therefore, the light conversion efficiency of the solar cell may be maintained highly.

At S503, in the solar cell panel, the vacuum window glazing is wholly or partially translucent, and inorganic materials including silicon, CIGS, CdTe, and the like, having no reduction in a degree of vacuum due to outgassing are appropriate to form the solar cell panel within the vacuum window glazing.

At S505, the space between the first sheet glass and the second sheet glass are vacuum-bonded to each other by the sealing material such as glass frit, or the like, so as to be maintained in a vacuum state. In this case, the plurality of spacers having a predetermined thickness may be formed between the first sheet glass and the second sheet glass so as to prevent the glass from being deformed and broken due to the atmospheric pressure.

When the amorphous silicon thin film solar cell is used as the solar cell panel, a dehydration phenomenon of the amorphous silicon thin film caused during the vacuum sealing process of the vacuum window glazing can be prevented by forming the amorphous silicon thin film at 300 to 500° C. higher than a general deposition temperature (200 to 300° C.). The quality of the solar cell can be maintained by performing the sealing process of the vacuum window glazing at the temperature lower than the deposition temperature of the amorphous silicon thin film. To this end, the sealing material of the vacuum window glazing is formed of materials which are melted at a lower temperature such as Indium (In), an indium alloy, or the like, or is melted by selectively heating only a portion of the sealing material using a laser or a local heater during the sealing process, and the solar cell region may be maintained at a relatively lower temperature.

At S507, in order to increase the strength of the vacuum window glazing and obtain the additional heat insulation effect, the third sheet glass is attached to the outside of the second sheet glass and then, the third sheet and the second sheet glass are bonded to each other using the sealing material. In this case, the degradation in heat insulation performance due to heat exchange can be prevented by injecting air, inert gases such as argon (Ar), krypton (Kr), xenon (Xe), or the like, between the second sheet glass and the third sheet glass. The heating layer may be further formed between the second sheet glass and the third sheet glass. In this case, a glass surface is heated by partially using power generated from the solar cell panel and thus, the cooling of the glass surface can be prevented, thereby increasing heating efficiency and preventing the glass window from being condensed and fogged.

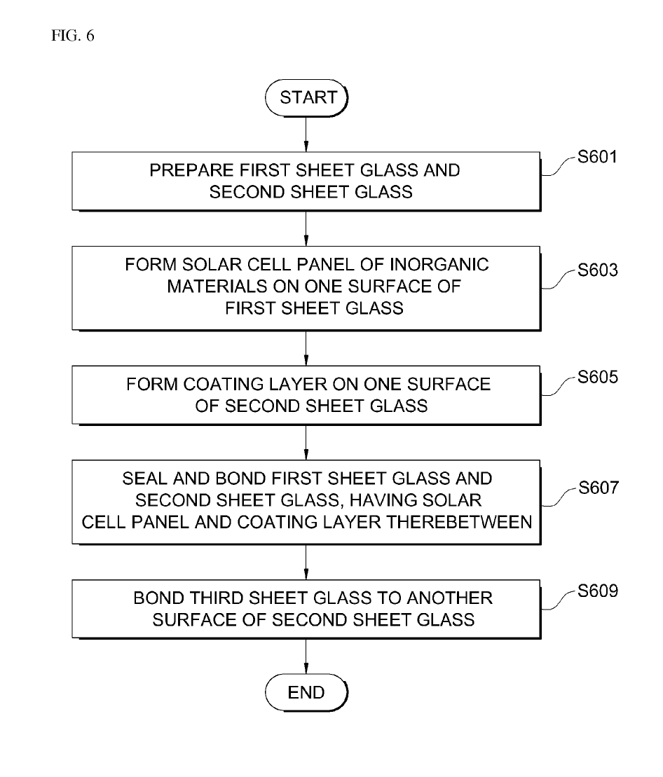

FIG. 6 is a flow chart of a method of manufacturing vacuum window glazing according to a second exemplary embodiment of the present disclosure.

Referring to FIG. 6, the method of manufacturing vacuum window glazing according to the second exemplary embodiment of the present disclosure includes: preparing the first sheet glass and the second sheet glass (S601), forming the solar cell panel of inorganic materials on one surface of the first sheet glass (S603), forming a coating layer on one surface of the second sheet glass, and sealing and bonding the first sheet glass and the second sheet glass, having the solar cell panel and the coating layer therebetween (S607), and bonding the third sheet glass to another surface of the second sheet glass (S609).

In the exemplary embodiment of the present disclosure, at S603, the solar cell panel is formed on one surface of the first sheet glass, and at S605, the coating layer having appropriate reflectivity is formed on one surface of the second sheet glass opposite to the first sheet glass. The light absorption of the solar cell panel can be increased by reflecting light transmitting the solar cell panel from the back surface through the coating layer. In this case, the reflectivity may be increased by optimizing the interval between the first sheet glass and the second sheet glass.

The exemplary embodiments of the present disclosure can produce power through the solar cell formed in the vacuum window glazing while more increasing the heat insulation effect of the vacuum window glazing, and can greatly improve the cooling and heating efficiency of the building using the outer wall covered with glass.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. Vacuum window glazing, comprising:
a first sheet glass;
a second sheet glass that is vacuum-bonded to the first sheet glass;
a vacuum layer that is formed between the first sheet glass and the second sheet glass; and
a solar cell panel that is formed on a surface of the second sheet glass in a direction of the vacuum layer.

2. The vacuum window glazing of claim 1, wherein the solar cell panel is wholly or partially translucent and is formed of inorganic materials including silicon, CIGS, or CdTe.

3. The vacuum window glazing of claim 1, wherein the first sheet glass is formed of low emissivity glass having high infrared reflectivity from sun light.

4. The vacuum window glazing of claim 1, further comprising:
a third sheet glass that is bonded to a surface of the second sheet glass in an opposite direction of the vacuum layer.

5. The vacuum window glazing of claim 4, wherein an inert gas is injected between the second sheet glass and the third sheet glass.

6. The vacuum window glazing of claim 4, further comprising:
a heating layer formed between the second sheet glass and the third sheet glass.

7. Vacuum window glazing, comprising:
a first sheet glass;
a second sheet glass that is vacuum-bonded to the first sheet glass;
a vacuum layer that is formed between the first sheet glass and the second sheet glass;
a solar cell panel that is formed on a surface of the first sheet glass in a direction of the vacuum layer; and
a coating layer that is formed on a surface of the second sheet glass in a direction of the vacuum layer and has predetermined reflectivity.

8. The vacuum window glazing of claim 7, wherein the solar cell panel is wholly or partially translucent and is formed of inorganic materials including silicon, CIGS, or CdTe.

9. The vacuum window glazing of claim 7, further comprising:
a third sheet glass that is bonded to a surface of the second sheet glass in an opposite direction of the vacuum layer.

10. The vacuum window glazing of claim 9, further comprising:
a heating layer formed between the second sheet glass and the third sheet glass.

11. Vacuum window glazing, comprising:
a first sheet glass;
a second sheet that is vacuum-bonded to the first sheet glass;
a vacuum layer that is formed between the first sheet glass and the second sheet glass;
a third sheet glass that is bonded to the second sheet glass in an opposite direction of the vacuum layer; and
a solar cell panel that is formed between the second sheet glass and the third sheet glass,
wherein the solar cell panel is formed of organic materials including a dye-sensitized solar cell (DSSC).

12. A method for manufacturing vacuum window glazing having a vacuum layer between a first sheet glass and a second sheet glass, the method comprising:
forming a solar cell panel of inorganic materials on a surface of the second sheet glass in a direction of the vacuum layer; and
sealing and bonding the first sheet glass and the second sheet glass.

13. The method of claim 12, wherein the solar cell panel is formed by using an amorphous silicon thin film, and the amorphous silicon thin film is deposited at a temperature between 300° C. and 500° C.

14. The method of claim 13, wherein the sealing and bonding is performed at a temperature lower than the deposition temperature of the amorphous silicon thin film.

15. The method of claim 12, further comprising:
bonding a third sheet glass to a surface of the second sheet glass in an opposite direction of the vacuum layer.

16. The method of claim 15, further comprising:
injecting an inert gas between the second sheet glass and the third sheet glass.

17. A method for manufacturing vacuum window glazing having a vacuum layer between a first sheet glass and a second sheet glass, the method comprising:
forming a solar cell panel of inorganic materials on a surface of the first sheet glass in a direction of the vacuum layer;
forming a coating layer on a surface of the second sheet glass in a direction of the vacuum layer direction; and
sealing and bonding the first sheet glass and the second sheet glass.

18. The method of claim 17, further comprising:
bonding a third sheet glass to the surface of the second sheet glass in an opposite direction of the vacuum layer.
